(19) United States
(12) Patent Application Publication
(10) Pub. No.: US 2005/0048774 A1
(43) Pub. Date: Mar. 3, 2005

(54) Method for manufacturing semiconductor device

(75) Inventor: Hiroshi Kitajima, Tsukuba-shi (JP)

Correspondence Address: LEYDIG VOIT & MAYER, LTD, 700 THIRTEENTH ST. NW, SUITE 300, WASHINGTON, DC, 20005-3960, US

(73) Assignee: Semiconductor Leading Edge Technologies, Inc., Tsukuba-shi (JP)

(21) Appl. No.: 10/925,988

(22) Filed: Aug. 26, 2004

(30) Foreign Application Priority Data
Sep. 1, 2003 (JP) 2003-308805

(51) Int. Cl. H01L 21/4763

(52) U.S. Cl. 438/682

(57) ABSTRACT

After forming a gate insulating film and a gate electrode on a substrate, ion implantation is performed to form a doped region. Thereafter, ions are implanted in the doped region and the gate electrode to form an amorphous layer on the doped region and the gate electrode. The amorphous layer is subjected to heat treatment at temperatures of 550° C. to 650° C. and recrystallized. Thereafter, a material film is formed for forming a silicide layer, at least on the doped region and the gate electrode, and heat treatment is performed so the Si of the doped region and the gate electrode reacts with said material film to form a silicide layer. Furthermore, the material film that has not reacted is removed. The thickness of the amorphous layer formed is substantially identical to the thickness of the silicide layer.

### BACKGROUND OF THE INVENTION

1. Field of the Invention

The present invention relates to a method for manufacturing a semiconductor device. More specifically, the present invention relates to a method for manufacturing a semiconductor device that has transistors of a salicide structure having a silicide layer formed on a diffusion layer.

2. Background Art

With higher integration and miniaturization of semiconductor devices in recent years, demand for lowering the resistance of semiconductor devices has increased, and various techniques for lowering the resistance has been studied. In order to reduce the resistance of transistors by improving ohmic contact with the source-drain electrode, and at the same time, by lowering resistance in the lateral direction, a salicide structure has been used. The salicide structure is a structure wherein self-aligned silicide is formed on the surfaces of the gate electrode and the diffusion layer.

FIG. 7 is a graph showing the relationship between the length of a silicide region in the channel direction and the parasitic resistance of a transistor having a channel width of 1 μm, in terms of the contact resistance of silicon/silicide boundaries as the parameter.

With higher miniaturization of semiconductor devices, the length of a silicide region in the channel direction has been reduced. However, as FIG. 7 shows, if the length of a silicide region is reduced, the contact resistance of the boundary of the silicide layer with the source/drain region increases. Therefore, the progress of miniaturization makes the reduction of contact resistance difficult.

On the other hand, according to ITRS (The International Technology Roadmap for Semiconductors), the target value of the parasitic resistance of a transistor in the 65-nm technology node is 19% or less of the total resistance of the transistor.

In the 65-nm technology node, for example, the length of a silicide region in the channel direction is 130 nm. In order to make the parasitic resistance of a transistor 19% or less in this case, the contact resistance of an nMOS (one side) and a pMOS (one side) must be 90 Ω·μm or lower and 170 Ω·μm or lower, respectively.

Here, in a transistor having a salicide structure, the most of the parasitic resistance is occupied by the contact resistance of the boundary of the silicide layer with the source/drain region, i.e., the silicon/silicide boundary. Therefore, in order to make the parasitic resistance 19% or less of the total resistance, the contact resistance must be 19% or less of the total resistance. Specifically, when the length of the silicide region in the channel direction is 130 nm, the contact resistance on an n-type diffusion layer (n+) and a p-type diffusion layer (p+) must be 1.5×10⁻⁷ Ω·cm² or lower and 2.8×10⁻⁷ Ω·cm² or lower, respectively.

In present techniques, however, the contact resistance of a transistor even using the above-described salicide structure on an n-type diffusion layer (n+) and a p-type diffusion layer (p+) is about 2.0×10⁻⁷ Ω·cm² to 3.0×10⁻⁷ Ω·cm², and 4.0×10⁻⁷ Ω·cm² to 5.0×10⁻⁷ Ω·cm², respectively. Therefore, it is difficult to make the parasitic resistance of a transistor 19% or less of the total resistance only by using the conventional salicide structure.

### SUMMARY OF THE INVENTION

Therefore, the object of present invention is to solve the above-described problems, and to provide a method for manufacturing a semiconductor device having transistors of reduced contact resistance.

According to one aspect of the present invention, in a method for manufacturing a semiconductor device, a gate insulating film and a gate electrode are formed on a substrate, and a diffusion layer is formed on the substrate. An amorphous layer is formed on the surface of the diffusion layer and the surface of the gate electrode by implanting ions into the surface of the diffusion layer and the surface of the gate electrode. First heat treatment at a temperature of 550° C. to 650° C. is performed. A material film for forming a silicide layer is formed at least in the surface of the diffusion layer and the surface of the gate electrode. Second heat treatment is performed to allow Si on the surface of the diffusion layer and the surface of the gate electrode to react with the material film to form a silicide layer. The material film that has not reacted is removed. Thickness of the amorphous layer formed is substantially identical with the thickness of the silicide layer.

According to another aspect of the present invention, in a method for manufacturing a semiconductor device a gate insulating film and a gate electrode are formed on a substrate, and a diffusion layer is formed on the substrate. An amorphous layer is formed on the surface of the diffusion layer and the surface of the gate electrode by implanting ions into the surface of the diffusion layer and the surface of the gate electrode. First heat treatment at a temperature of 550° C. to 650° C. is performed. A material film for forming a silicide layer is formed at least on the surface of the diffusion layer and the surface of the gate electrode. Second heat treatment at a temperature of about 250° C. to 350° C. is performed to allow Si on the surface of the diffusion layer and the surface of the gate electrode to react with the material film to form a silicide layer. The material film that has not reacted is removed. Third heat treatment at a temperature at least lower than the temperature of the first heat treatment is performed. Thickness of the amorphous layer is substantially identical with the thickness of the silicide layer.

Other and further objects, features and advantages of the invention will appear more fully from the following description.

### BRIEF DESCRIPTION OF THE DRAWINGS

FIG. 1 is a schematic sectional view for illustrating a semiconductor device 100 according to the first embodiment of the present invention;

FIG. 2 is a flow diagram for illustrating a method for manufacturing a semiconductor device 100 according to the first embodiment of the present invention;

FIGS. 3 to 6 are schematic sectional views for illustrating the states in the manufacturing steps of the semiconductor device 100;

FIG. 7 is a graph showing the relationship between the length of a silicide region in the channel direction and the parasitic resistance of a transistor having a channel width of 1 μm, in terms of the contact resistance of silicon/silicide boundaries as the parameter.

### DETAILED DESCRIPTION OF THE PREFERRED EMBODIMENTS

The embodiments of the present invention will be described below referring to the drawings. In the drawings, the same or corresponding parts will be denoted by the same reference numerals, and the description thereof will be simplified or omitted.

First Embodiment

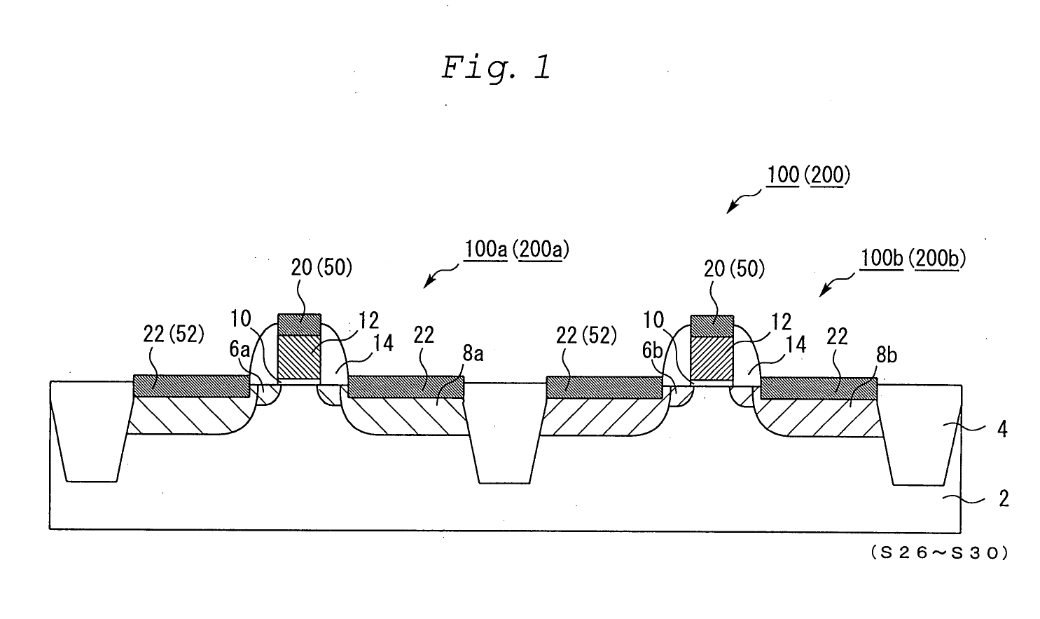

FIG. 1 is a schematic sectional view for illustrating a semiconductor device 100 according to the first embodiment of the present invention.

As FIG. 1 shows, the semiconductor device 100 according to the first embodiment of the present invention is composed of a cMOS (complementally metal oxide semiconductor) having a pMOS (p-channel metal oxide semiconductor) 100a and an nMOS (n-channel metal oxide semiconductor) 100b. In this specification, the region for forming the pMOS 100a is referred to as “active region for pMOS” and the region for forming the nMOS 100b is referred to as “active region for nMOS”, for simplification.

In the semiconductor device 100, element-isolating regions 4 are formed in an Si substrate 2. In an active region for pMOS isolated by the element-isolating regions 4, a p-type extension 6a having a relatively low impurity content is formed, and a p-type source-drain region 8a, which is a diffusion layer having a high impurity content is formed outside the extension 6a. Similarly in an active region for nMOS, an n-type extension 6b having a relatively low impurity content is formed, and a n-type source-drain region 8b, which is a diffusion layer having a high impurity content is formed outside the extension 6b.

A gate electrode 12 is formed on the area of the Si substrate 2 in each region sandwiched by the source-drain region 8a or 8b through a gate insulating film 10. A sidewall 14 is formed on the side of each gate electrode 12. CoSi₂ layers 20 and 22 are formed on the surface of the gate electrode 12 and the surface of the source-drain region 8, respectively. In the semiconductor device 100, by forming the CoSi₂ layers 20 and 22 to be a salicide structure, the resistance of the transistor can be lowered.

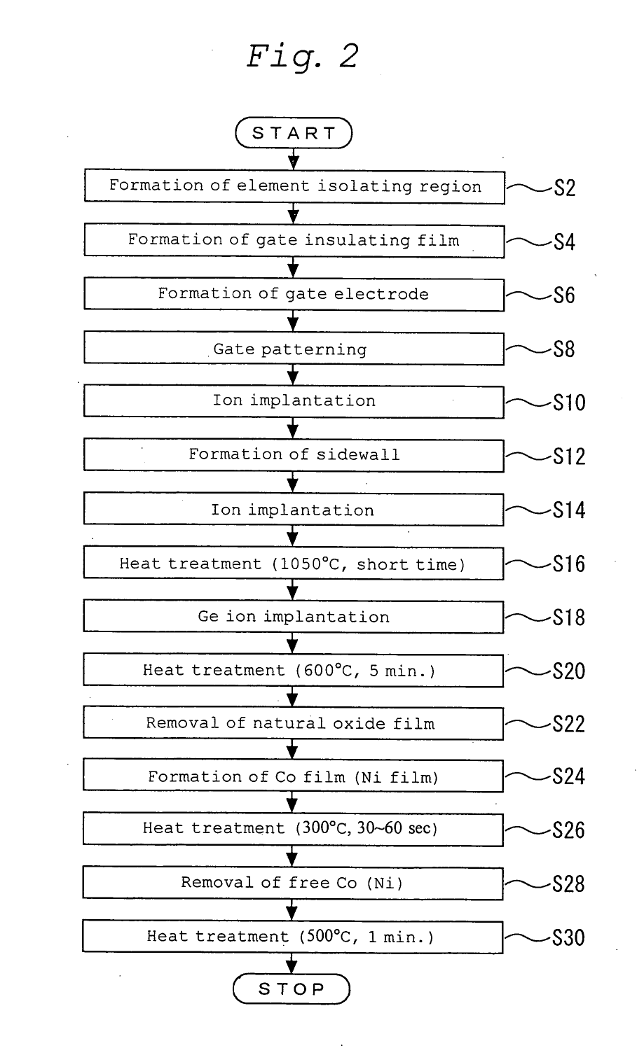

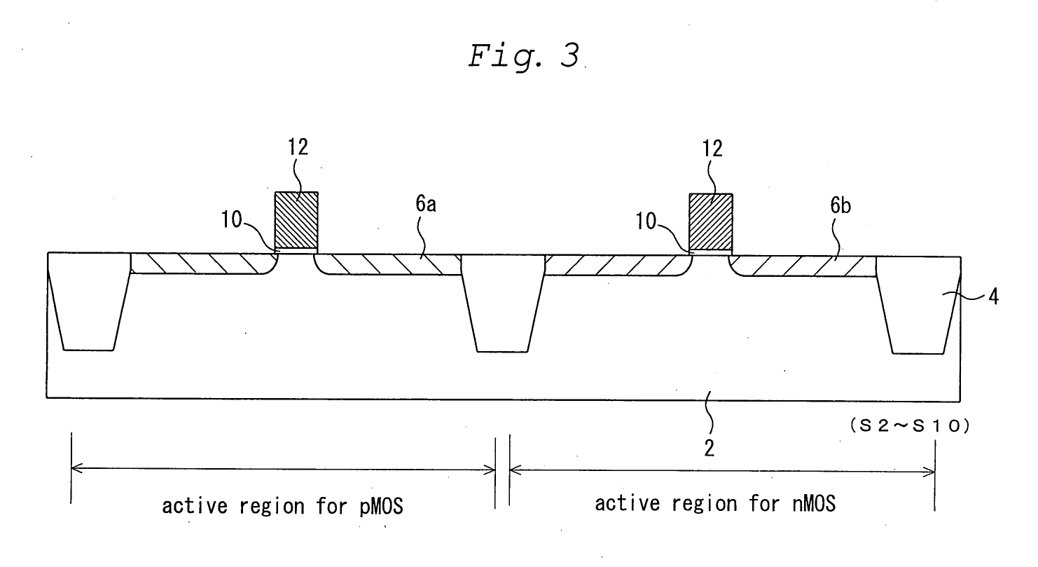

FIG. 2 is a flow diagram for illustrating a method for manufacturing a semiconductor device 100 according to the first embodiment of the present invention. FIGS. 3 to 6 are schematic sectional views for illustrating the states in the manufacturing steps of the semiconductor device 100.

The method for manufacturing a semiconductor device 100 according to the first embodiment of the present invention will be specifically described below referring to FIGS. 1 to 6.

First, as FIG. 3 shows, element-isolating regions 4 are formed on a Si-substrate 2, and is isolated into an active region for pMOS and an active region for nMOS (Step S2).

Next, the material film of the gate insulating film 10 is formed on the Si substrate 2 (Step S4), and the material film of a gate electrode 12 is laminated thereon (Step S6). Thereafter, the gate is patterned (Step S8). Here, a resist mask is formed on the gate electrode 12 through lithography, developing, and the like, and the material films of the gate electrode 12 and the gate insulating film 10 are etched to perform the patterning of the gate. Thereafter, the resist mask is removed.

Next, ion implantation is performed into each of active regions for pMOS and nMOS (Step S10). Here, a resist mask coating the active region for nMOS is first formed, and a p-type impurity is implanted into the active region for pMOS using the resist mask and the gate electrode 12 as masks. Thereafter, the resist mask is removed. Next, a resist mask coating covering the active region for pMOS is formed, and a n-type impurity is implanted into the active region for nMOS using the resist mask and the gate electrode 12 as masks. Thereby, the extensions 6a and 6b having a low impurity content are formed in the both sides of the gate electrode 12 on the surface of the Si substrate 2 of each active region, respectively.

In the process up to here, although the formation of the well, the ion implantation for the channel, the ion implantation for the pocket, or the formation of a thin spacer insulating film on the side of the gate are actually performed as required, these are performed using conventional methods, and therefore the description thereof is omitted in the description of the first embodiment.

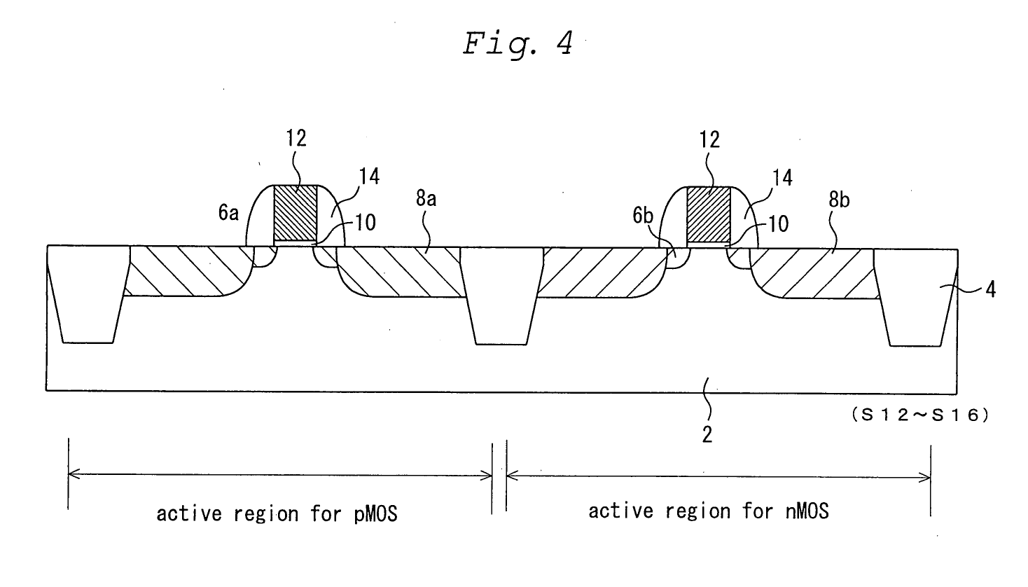

Next, as FIG. 4 shows, a sidewall 14 is formed on the side of each gate electrode 12 (Step S12). Here, after depositing an insulating film on the Si substrate 2 so as to bury the gate electrode 12 and the like, anisotropic dry etching is performed.

Next, ion implantation is performed into each of the active regions for pMOS and nMOS (Step S14). Here, similar to the formation of extensions, a resist mask coating the nMOS region is first formed. Then, a p-type impurity is implanted into the pMOS region using the resist mask, the gate electrode 12 and the sidewall 14 as masks. Thereafter, the resist mask is removed. Next, a resist mask coating the pMOS region is formed. Then, an n-type impurity is implanted into the nMOS region using the resist mask, the gate electrode 12 and the sidewall 14 as masks, and the resist mask is removed. Thereby, a source-drain regions 8a and 8b, which are diffusion layers having a relatively high impurity content are formed in the outside of the extension 6 of each active region.

Thereafter, heat treatment is performed at 1050° C. for a short time (Step S16). Thereby, the impurities implanted into the extensions 6a and 6b and the source-drain regions 8a and 8b are activated.

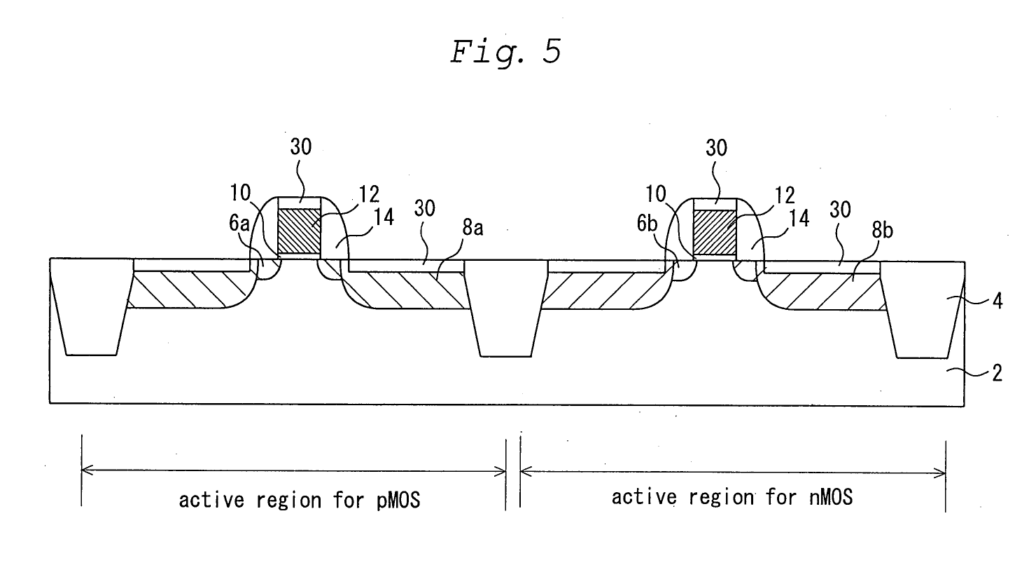

Next, Ge ions are implanted into the entire surface of the substrate 2 (Step S18). Here, the implantation energy is about 10 keV, and the dose is about 3×10⁻¹⁴ cm². Thereby, as FIG. 5 shows, amorphous layers 30 are formed on the surfaces of the gate electrode 12 and the source-drain region 8. The depth of these amorphous layers 30 is about 20 nm.

Thereafter, heat treatment is performed (Step S20). The heat treatment temperature is about 600° C., and the time is about 5 minutes. Thereby, the amorphous layers 30 are re-crystallized. Thereafter, the natural oxide film (not shown) formed during the heat treatment is removed (Step S22).

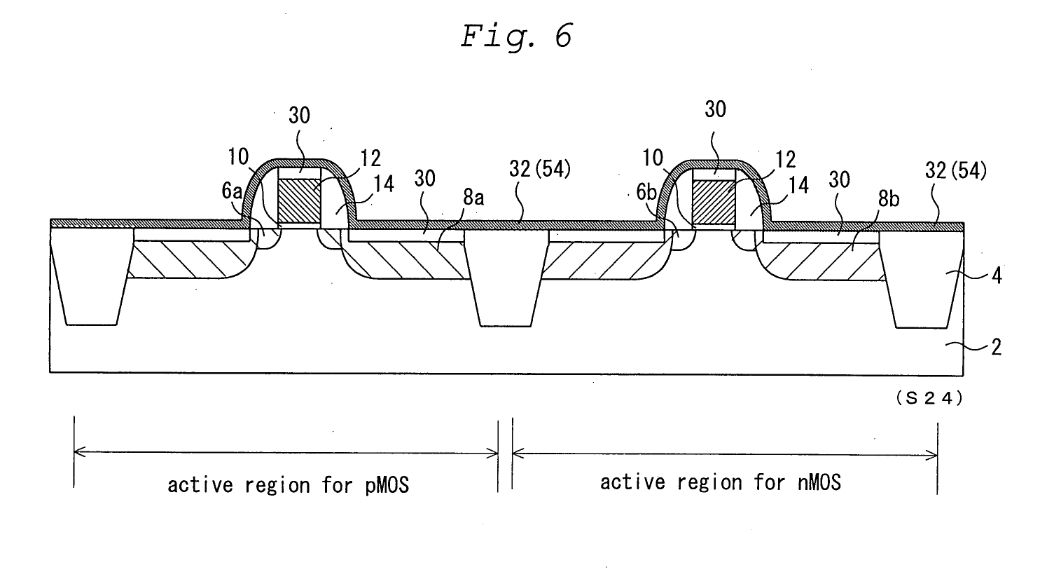

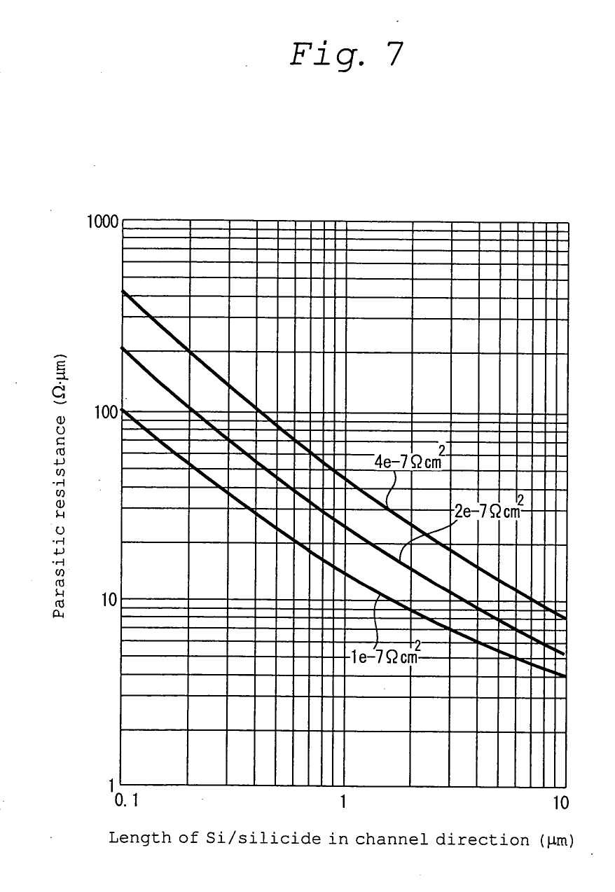

Next, as FIG. 6 shows, a Co film 32 is formed on the exposed surface of the substrate 2 (Step S24). Here, a sputtering method is used. The thickness of the formed Co film 32 is about 10 nm.

Next, heat treatment is performed (Step S26). Here, the heat treatment temperature is about 300° C., and the time is about 30 to 60 seconds. Thereby, Co in the Co film 32 reacts with Si in the source-drain region 8 or Si in the gate electrode 12 to form CoSi. Thereafter, Co in the Co film 32 that has not reacted with Si is removed (Step S28). Furthermore, heat treatment is performed (Step S30). Here, the heat treatment temperature is about 500° C., and the time is about 1 minute. Thereby, CoSi₂ further reacts to form CoSi₂ layers 20 and 22. Thereby, a transistor having a salicide structure wherein CoSi₂ layers 20 and 22 are formed on the gate electrode 12 and the source-drain region 8, respectively, as FIG. 1 shows, can be obtained.

Thereafter, an interlayer insulating film in which the gate electrode 12 and the sidewall 14 are buried is formed, and a contact that reaches the CoSi₂ film 22 is formed. Furthermore, a metal wiring is formed on the contact plug. By repeating such steps, a semiconductor device having a multi-layer wiring can be obtained. In this case, the heat treatment temperature after the formation of the silicide layer is preferably 600° C. or below, and, more preferably, 550° C. or below.

According to the first embodiment, as described above, an amorphous layer 30 is formed on the source-drain region 8 and the gate electrode 12, the amorphous layer 30 is re-crystallized by heat treatment, and CoSi₂ layers 20 and 22 are formed. Thereby, the contact resistance at the boundary between the CoSi₂ layer 22, which is a silicide layer, and the source-drain region 8, which is a diffusion layer, namely, at the silicon/silicide boundary can be reduced.

Specifically, when a silicon surface layer containing a high content of impurities introduced by ion implantation is subjected to heat treatment at a high temperature of about 1000° C., a part of the impurities are diffused and activated. At this time, however, there is a layer that is not affected or activated by the heat treatment on the outermost surface. The content of the activating impurities is as low as about 1×10²⁰ cm³. However, when the surface is made amorphous, the impurities on the outermost surface are easily diffused. Furthermore, when the amorphous layer is re-crystallized at a temperature about 600° C., a layer having a low resistance can be formed even in the same junction depth. Therefore, by further forming a silicide layer and forming a salicide structure, a reduced contact resistance at the silicon/silicide boundary can be realized in the transistor 100.

Specifically, according to the method described in the first embodiment, the contact resistance can be as low as 1.0×10⁻⁷ Ω·cm² to 1.5×10⁻⁷ Ω·cm² on an n-type diffusion layer (n+) and 2.0×10⁻⁷ Ω·cm² to 3.0×10⁻⁷ Ω·cm² on a p-type diffusion layer (p+).

In the first embodiment, the formation of a CMOS was described. In general, when both nMOS and pMOS are present as in this case, the nMOS has a higher impurity content in the surface of the source-drain region than the pMOS. Therefore, if the silicide layer of the cMOS is formed using conventional methods, it is considered that the reaction rate for siliciding in the nMOS side is larger than the reaction rate for siliciding in the pMOS side. Thus, when reactions having different reaction rates are simultaneously performed in active regions for pMOS and nMOS formation, it is considered that the siliciding reaction proceeds excessively to increase the leakage current.

However, in the first embodiment, by performing amorphous conversion and then re-crystallization of the amorphous layer after forming the source-drain regions 8a and 8b, impurity-content distribution in the source-drain regions 8a and 8b can be equalized. Therefore, even when the active regions for pMOS and nMOS are simultaneously silicided, the difference of reaction rate between both regions can be minimized. Hence, a cMOS having favorable device characteristics with suppressed leakage current can be obtained.

However, the present invention is not necessarily applied only to the cMOS, but can be applied to an nMOS or a pMOS, and the effect of lowering resistance by the re-crystallization of the diffusion layer can be achieved also in this case. Furthermore, the present invention is not limited to MOS transistors, but can be applied to the case wherein the surface of the diffusion layer must be silicided.

In the first embodiment, there was described the of CoSi₂ layers 20 and 22, wherein after forming CoSi by performing heat treatment at a temperature of about 300° C., Co is removed; and then CoSi₂ layers 20 and 22 are formed by performing heat treatment at a temperature of about 500° C. This is because a disilicide having a lower resistance can be obtained when the disilicide is formed using a two-stage heat treatment than the disilicide formed using a one-stage heat treatment. However, the present invention is not limited to the formation of the disilicide using a two-stage heat treatment, but the disilicide may be formed using a one-stage heat treatment.

In the first embodiment, there was described the formation of CoSi₂ layers 20 and 22, wherein heat treatment is first performed at a temperature of about 300° C., and then heat treatment is performed at a temperature of about 500° C. However, in the present invention, the temperature of each heat treatment is not limited thereto. However, in order to form a low-resistance silicide, the temperature of the first heat treatment is preferably 250° C. to 350° C. The second heat treatment is preferably performed at a temperature of 600° C. or below, more preferably 550° C. or below. It is also preferable in order to suppress the variation of the profile of the re-crystallized diffusion layer that the temperature is at least lower than the temperature of heat treatment for re-crystallization after the formation of the amorphous layer (Step S20).

Second Embodiment

The transistor 200 in the second embodiment is similar to the transistor 100 described in the first embodiment. However, in the transistor 100, CoSi₂ layers 20 and 22 are formed on the surfaces of the source-drain region 8 and the gate electrode 12, respectively; whereas in the transistor 200 of the second embodiment, NiSi layers 50 and 52 are formed.

The method for manufacturing the transistor 200 in the second embodiment is similar to the method for manufacturing the transistor 100 described in the first embodiment.

In the method for manufacturing the transistor 200, however, the energy for Ge-ion implantation (Step S18) is about 5 keV, which is a half of the energy used in the first embodiment. In place of the formation of the Co film 32 (Step S24), an Ni film 54 of a thickness of about 10 nm is formed. Therefore, in the following heat treatment (Step S26), Ni in the Ni film 54 reacts with Si in the gate electrode 12 and the source-drain region 8 to form NiSi. In this case, the temperature for heat treatment is 400° C. to 500° C. Thereafter, Ni that has not reacted is removed (Step S28). When the NiSi layers 50 and 52 are formed, heat treatment is performed only once (Step S26), and heat treatment after the removal of free Ni (Step S30) is not performed.

Other steps are carried out in the same manner as described in the first embodiment to form a transistor 200 having NiSi layers 50 and 52 formed on the gate electrode 12 and the source-drain region 8, respectively. Also in the same manner as in the first embodiment, a multi-layer wiring is formed on the transistor 200 to form a semiconductor device. In this case, it is required to control the treatment temperature for forming the NiSi layers 50 and 52 to a low temperature of about 400° C. to 5000C or below.

When Ni is used, the formed silicide layer is a monosilicide (NiSi) layer. Therefore, the depth of the formed silicide layer is about half the depth of the Co film wherein a disilicide (CoSi₂) layer is formed. For example, in the first embodiment wherein a Co film of a thickness of 10 nm is formed, the silicon/silicide boundary is about 20 nm below the original silicon surface. Whereas, when an Ni film of a thickness of about 10 nm is formed, the silicon/silicide boundary is about 10 nm below the original silicon surface. Therefore, in the second embodiment, the thickness of the formed amorphous layer 30 can be about 10 nm, a half the thickness in the first embodiment, and the energy of implanting Ge ions can be about 5 keV, a half the energy in the first embodiment.

According the second embodiment, as described above, a transistor of further low contact resistance can be obtained by forming NiSi layers 50 and 52, compared with the case wherein CoSi₂ layers 20 and 22 are formed. Specifically, according to the method described in the second embodiment, the contact resistance can be as low as 0.7×10⁻⁷ Ω·cm² to 1.0×10⁻⁷ Ω·cm² on an n-type diffusion layer (n+) and about 1.0×10⁻⁷ Ω·cm² to 2.0×10⁻⁷ Ω·cm² on a p-type diffusion layer (p+).

When cobalt is used, since there is a problem of the formation of defective silicide if the Ge content is high, the dose of Ge has an upper limit. However, in the case of Ni, good results can be obtained within a relatively wide range between 1×10¹⁴ cm² and 5×10¹⁴ cm⁻².

When the NiSi layers are formed using one heat treatment, the adequate temperature is about 400° C. to 500° C., and in the subsequent steps must be carried out at a low temperature to avoiding the elevation of the resistance of the NiSi layers themselves. In the second embodiment, the silicide layers are formed using one heat treatment. However, the present invention is not limited thereto, but heat treatment can be performed after removing free Ni from the Ni film 54. In this case, the temperature for heat treatment immediately after the formation of the Ni film 54 (Step S26) is preferably about 300° C., and the temperature for heat treatment after the removal of the Ni film 54 is preferably about 500° C.

In the embodiments, Ge ions are implanted to form an amorphous layer 30. However, the present invention is not limited to the use of Ge ions, but for example, the Ge ions may be substituted by Si ions, F ions, GeF₂ ions, or SiF₂ ions. When fluorine is contained, the effect of reducing junction leakage current can also be obtained.

In the first embodiment, the energy for implanting Ge ions is about 10 keV, and in the second embodiment, it is about 5 keV. This is because the energy is made proportional to the depth of the formed silicide layer. If ions other than Ge ions are used, the implanting energy can be adjusted so as to form the film of the same thickness as the thickness of the silicide layer to be subsequently formed. However, in the present invention, the energy for ion implantation is not necessarily limited to be proportional to the depth of the formed silicide layer. Even if the depth of the formed amorphous layer differs from the depth of the silicide layer, the effect of reducing the resistance can be obtained to some extent.

In the embodiments, heat treatment at about 600° C. was performed to re-crystallize the amorphous layer. In the present invention, the temperature for heat treatment is not limited thereto. However, the temperature for heat treatment is preferably 550° C. to 650° C. If it is below 550° C., it must be considered that the layer resistance may elevate, or re-crystallization may become uneven. In this case, for example, adjustment by the time for heat treatment and the like is desired. If the temperature for heat treatment is above 650° C., the elevation of contact resistance can be considered. Therefore, adjustment such as shortening the time for heat treatment is desired

For example, in the first and second embodiments, the source-drain region 8 corresponds to the diffusion layer; and the CoSi₂ layer 20 and 22, and the NiSi layer 50 and 52 correspond to the silicide layers of the present invention. For example, the Co film 32 and the Ni film 54 correspond to the material films of the present invention.

For example, in the first and second embodiments, the step for forming the electrode of the present invention is carried out by carrying out Steps S4 to S8; and the step for forming the diffusion layer is carried out by carrying out Steps S10 and S14. For example, the step for forming an amorphous layer and the step for performing a first heat treatment are carried out by carrying out Steps S18 and S20, respectively. For example, the step for forming a material film, the step for performing a second heat treatment, and the step for removing free Co or Ni are carried out by carrying out Steps S24, S26, and S28, respectively. For example, the step for performing a third heat treatment is carried out by carrying out Step S30 in the first embodiment.

The features and the advantages of the present invention as described above may be summarized as follows.

According to one aspect of the present invention, after forming a diffusion layer, ion implantation is performed to form an amorphous layer, and then the amorphous layer is re-crystallized using heat treatment to form a silicide layer. Thereby, the contact resistance in the boundary of the silicide layer with the diffusion layer can be reduced. Thereby, the proportion of the parasitic resistance of the transistor to the total resistance of a semiconductor device can be reduced, and a semiconductor device having favorable device characteristics can be obtained.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2003-308805, filed on Sep. 1, 2004 including specification, claims, drawings and summary, on which the Convention priority of the present application is based, are incorporated herein by reference in its entirety.

1. A method for manufacturing a semiconductor device comprising:
forming a gate insulating film and a gate electrode on a substrate,
forming a doped region in said substrate,
forming an amorphous layer on said doped region and said gate electrode by implanting ions into said doped region and said gate electrode,
first heat treating at a temperature of 550° C. to 650° C.,
forming a material film for forming a silicide layer at least on said doped region and said gate electrode,
second heat treating so that Si on said doped region and said gate electrode reacts with said material film to form a silicide layer, and
removing any parts of said material film that have not reacted to form said silicide layer, wherein said amorphous layer is formed to be substantially identical in thickness with said silicide layer that is subsequently formed.

2. The method for manufacturing a semiconductor device according to claim 1, including
in forming said amorphous layer by implanting ions having energies in a range from 8 keV to 13 keV, and at a dosage in a range from 2×10¹⁴ cm⁻² to 4×10¹⁴ cm⁻², and
forming a Co film as said material film.

3. The method for manufacturing a semiconductor device according to claim 1, including
in forming said amorphous layer by implanting ions having energies in a range from 3 keV to 7 keV, and at a dosage in a range from 1×10¹⁴ cm² to 5×10¹⁴ cm⁻², and
forming an Ni film as said material film.

4. The method for manufacturing a semiconductor device according to claim 1, further comprising third heat treating, after removing any parts of said material film that have not reacted.

5. The method for manufacturing a semiconductor device according to claim 1, including forming said amorphous layer using ions selected from the group consisting of Ge ions, Si ions, F ions, GeF₂ ions, and SiF₂ ions.

6. A method for manufacturing a semiconductor device comprising:
forming a gate insulating film and a gate electrode on a substrate,
forming a doped region in said substrate,
forming an amorphous layer on said doped region and said gate electrode by implanting ions into said doped region and said gate electrode,
first heat treating at a temperature of 550° C. to 650° C.,
forming a material film for forming a silicide layer at least said doped region and said gate electrode,
second heat treating at a temperature of about 250° C. to 350° C. so that Si on said doped region and said gate electrode reacts with the material film to form a silicide layer,
removing any parts of said material film that have not reacted to form said silicide layer, and
third heat treating at a temperature lower than the temperature of said first heat treating, wherein said amorphous layer is formed to be substantially identical in thickness with the silicide layer that is subsequently formed.

7. The method for manufacturing a semiconductor device according to claim 6, including
in forming said amorphous layer implanting ions having energies in a range from 8 keV to 13 keV, and at a dosage in a range from 2×10¹⁴ cm⁻² to 4×10¹⁴ cm⁻², and
forming a Co film as said material film.

8. The method for manufacturing a semiconductor device according to claim 6, including
in forming said amorphous layer implanting ions having energies in a range from 3 keV to 7 keV, and at a dosage in a range from 1×10¹⁴ cm⁻² to 5×10¹⁴ cm⁻², and
forming an Ni film as said material film.

9. The method for manufacturing a semiconductor device according to claim 6, including forming said amorphous layer using ions selected from the group consisting of Ge ions, Si ions, F ions, GeF₂ ions, and SiF₂ ions.
